(19) United States
(12) Patent Application Publication
(10) Pub. No.: US 2025/0230039 A1
(43) Pub. Date: Jul. 17, 2025

(54) MEMS ARM FOR MICROELECTROMECHANICAL SYSTEM

(71) Applicant: Taiwan Semiconductor Manufacturing Company, LTD., Hsinchu (TW)

(72) Inventor: Shih-Yu Liao, Hsinchu (TW)

(21) Appl. No.: 18/411,422

(22) Filed: Jan. 12, 2024

(51) Int. Cl. B81C 1/00; B81B 3/00

(52) U.S. Cl. CPC B81C 1/0015; B81B 3/0021; B81B 2203/0118; B81B 2203/0136; B81C 2201/0132

(57) ABSTRACT

To fabricate a microelectromechanical (MEMS) arm, a release structure is disposed on a base structure having an anchor structure. A lower protective dielectric layer is deposited on the release structure. An arm structure is formed on the lower protective dielectric layer and on the anchor structure. The release structure is removed by etching with a fluorine-based etchant to form the MEMS arm secured to the anchor structure and including the arm structure and the lower protective dielectric layer. The anchor structure may be a first electrode, and the base structure further includes a second electrode and a spacer interposed between the first electrode and the second electrode. The release structure disposed on the second electrode and on the spacer, and the etching further removes the spacer. The result is a capacitive MEMS structure with the cantilevered arm capacitively coupled with the second electrode.

### BACKGROUND

The following relates to the semiconductor device and manufacturing arts, microelectromechanical (MEMS) arts, MEMS actuator and sensor devices and fabrication, MEMS comb drives and fabrication thereof, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, and 4 diagrammatically illustrate sectional views of successive intermediate structures of a fabrication process for fabricating a MEMS arm.

FIG. 5 diagrammatically illustrates a sectional view of a MEMS arm formed by etching the intermediate structure of FIG. 4 using a fluorine-based etchant.

FIG. 6 diagrammatically illustrates a capacitive MEMS sensor including the MEMS arm of FIG. 5.

FIG. 7 diagrammatically illustrates a capacitive MEMS actuator including the MEMS arm of FIG. 5.

FIGS. 8, 9, and 10 diagrammatically illustrate sectional views of additional illustrative MEMS arm embodiments.

FIG. 11 diagrammatically illustrate a sectional view of a MEMS device including a driving comb suitably secured with an arm structure such as those shown in FIGS. 5 and 8-10.

FIGS. 12, 13, 14, 15, 16, 17, and 18 diagrammatically illustrate sectional views of intermediate structures of a fabrication process for fabricating the illustrative MEMS device of FIG. 11.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Microelectromechanical (MEMS) devices frequently include MEMS arm structures that can move in response to an external stimulus, or that can be actuated to move in response to an electrical input. For example, a MEMS arm in the form of a cantilevered arm made of a metal or other electrically conductive material can be arranged with its anchored end connected with a first electrode, and its free end disposed in proximity to a second electrode. In such a design, the first and second electrodes constitute a capacitive drive. The capacitance between the second electrode and the cantilevered arm will change as the cantilevered arm moves toward or away from the second electrode.

Such a capacitive MEMS cantilevered arm can be used as a sensor, where an input to be measured (i.e., sensed) modifies the position of the cantilevered arm respective to the second electrode. For example, the input could be acceleration which moves the cantilevered arm. In other types of MEMS-based sensors, sound waves or magnetic signals or so forth can be the input that is measured. For example, if the cantilevered arm has a magnetic material on its free end then the arm can move in response to an external magnetic field.

Such a capacitive MEMS cantilevered arm can alternatively serve as a MEMS actuator. In this case, a voltage or other electrical input across the first and second electrodes produces an electrostatic force on the cantilevered arm, thereby producing motion.

In some designs, the cantilevered arm may be a connector, with a component such as a comb attached to the free end of the cantilevered connector arm. Such a comb can provide stronger electrostatic interaction.

In some approaches for forming a MEMS arm, a sacrificial layer (also known as a release layer) is formed, followed by forming an arm structure (e.g. a patterned metal layer) that is destined to become the cantilevered arm. For example, the sacrificial layer can be made of a silicon material, while the arm structure is a patterned metal layer. A fluorine-based etching process then removes the release layer. Advantageously, fluorine-based etchants have high selectivity for etching silicon over metal, so that the fluorine-based etching removes the release layer while not removing the arm structure.

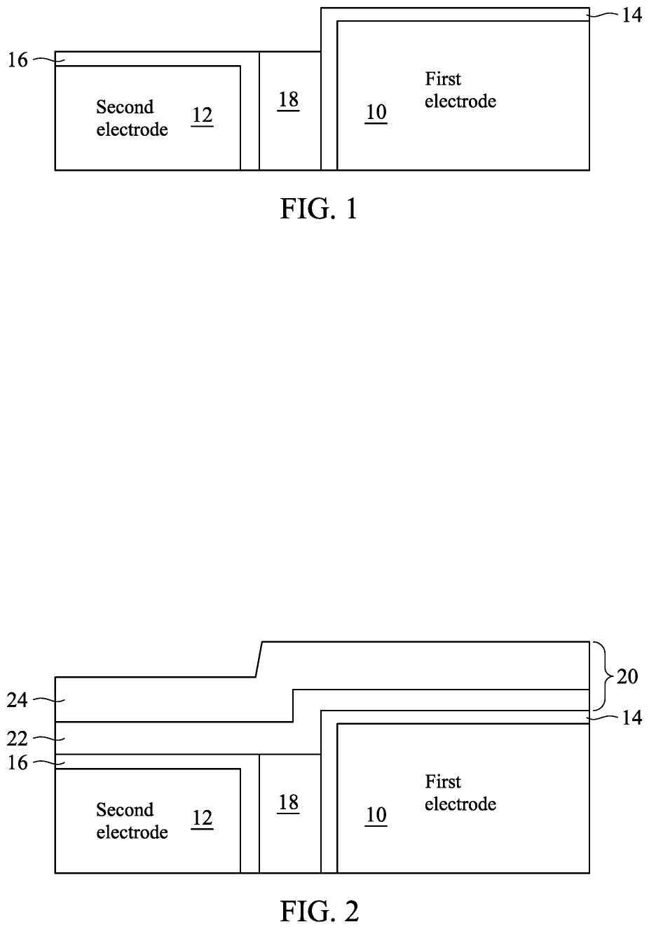

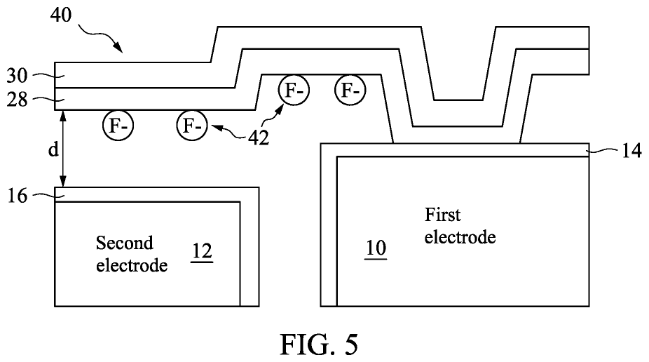

With reference to FIGS. 1-5, a process for fabricating a MEMS arm comprising a cantilevered arm is described. FIG. 5 illustrates the final structure including first and second electrodes 10 and 12 and a cantilevered arm 40, while FIGS. 1-4 show sectional views of successive steps in the fabrication thereof. FIG. 1 illustrates a base structure on which the cantilevered arm 40 is to be formed. The illustrative base structure is a capacitive drive including a first electrode 10 and a second electrode 12. The first and second electrodes 10 and 12 are suitably formed of an electrically conductive material. In some nonlimiting illustrative embodiments, the first electrode 10 comprises a silicon material, such as for example silicon, polysilicon, amorphous silicon, or a combination thereof, although other materials besides silicon are also contemplated. The first electrode 10 is coated with a first electrode protective dielectric layer 14; and similarly the second electrode 12 in some nonlimiting illustrative embodiments comprises a silicon material, such as for example silicon, polysilicon, amorphous silicon, or a combination thereof, although other materials besides silicon are also contemplated. The second electrode 12 is coated with a second electrode protective dielectric layer 16. The electrode protective dielectric layers 14 and 16 comprise a dielectric material that is not removed by the fluorine-based etchant destined to be used to remove the release layer. For example, the electrode protective dielectric layers 14 and 16 may, by way of nonlimiting illustrative example, comprise a silicon oxide (e.g., stoichiometric silicon dioxide, SiO₂, or a non-stoichiometric silicon oxide), a silicon nitride (e.g., stoichiometric Si₃N₄ or non-stoichiometric silicon nitride), a silicon carbide, a silicon oxynitrocarbide, or a glass such as an un-doped silicate glass (USG), a fluoride-doped silicate glass (FSG), a borophosphosilicate glass (BPSG), or various combinations thereof, although other materials are also contemplated. As a nonlimiting illustrative example, the electrode protective dielectric layers 14 and 16 may be in a range of 0.1-0.3 micron thick, although thicknesses outside of this range are also contemplated.

In other contemplated embodiments, the first and second electrodes 10 and 12 may comprise an electrically conductive material of a type that is not strongly etched by the fluorine-based etchant destined to be used to remove the release layer. For example, the first and second electrodes 10 and 12 could comprise a metal such as aluminum (Al) or copper (Cu), a metal alloy such as AlCu (optionally further including silicon, i.e., AlSiCu), a metal nitride such as titanium nitride (TiN) or tantalum nitride (TaN), or a combination thereof, although other materials are also contemplated. In these embodiments, the electrode protective dielectric layers 14 and 16 may optionally be omitted.

As further shown in FIG. 1, in addition to the capacitive drive comprising the electrodes 10 and 12, the base structure further includes a spacer 18 interposed between the first electrode 10 and the second electrode 12. The illustrative spacer 18 is destined to be removed by the fluorine-based etchant that will be used to remove the release layer. Hence, the spacer 18 should be made of a material that is strongly etched by the fluorine-based etchant, such as a silicon material (e.g., silicon, polysilicon, amorphous silicon, or a combination thereof, although other materials are also contemplated).

In other embodiments, it is contemplated for the spacer between the first and second electrodes 10 and 12 to be not removed by the fluorine-based etchant. In such alternative embodiments, the spacer should comprise a material that is electrically insulating so that the first and second electrodes 10 and 12 in the final fabricated capacitive MEMS structure are electrically isolated from one another.

The base structure of FIG. 1 can be fabricated in various ways. In one contemplated, photolithographically patterned etching of a substrate or layer comprising the silicon material destined to form the first and second electrodes 10 and 12 is performed to form a trench in the substrate or layer. A layer of the dielectric material of the electrode protective dielectric layers 14 and 16 is then deposited so as to coat the electrodes 10 and 12 with the respective electrode protective dielectric layers 14 and 16, followed by photolithographically controlled deposition to fill the trench with silicon material to form the spacer 18. In the illustrative example, the first electrode 10 is destined to be the anchor for the cantilevered arm, and to this end the first electrode 10 is higher than the second electrode 12 as seen in FIG. 1, so as to provide a step between the first and second electrodes 10 and 12. This can be done in various ways, such as photolithographically patterned deposition of additional silicon material to raise the height of the first electrode 10 (prior to forming the protective layer 14), or photolithographically patterned etching of silicon material to lower the height of the second electrode 12 (prior to forming the protective layer 16).

With reference now to FIG. 2, a release structure 20 is disposed on the base structure. The release structure 20 is suitably formed of a silicon material that is etched by the fluorine-based etchant that will be used in the subsequent release step. For example, the silicon structure 20 may comprise a silicon material such as silicon, polysilicon, amorphous silicon, or a combination thereof, although other materials besides silicon are also contemplated. In the illustrative example, the release structure 20 is formed of two different layers 22 and 24 of different silicon materials. For example, in one embodiment the first layer 22 comprises a silicon material that provides a smooth interface with the underlying first and second electrodes 10 and 12, such being formed as polysilicon using a deposition technique that provides small grains; while the second layer 24 comprises a silicon material that can be deposited with a faster deposition rate, such as polysilicon deposited with larger average grain size. This is merely a nonlimiting illustrative example. In one nonlimiting illustrative embodiment, the total thickness of the release structure 20 is about 1-2 microns, although larger or smaller thicknesses are also contemplated. The thickness of the release structure 20 will determine the unbiased spacing between the second electrode 12 and the cantilevered arm (which in turn will affect the unbiased capacitance), and hence the thickness of the release structure 20 is thus chosen to provide the design-basis unbiased separation/capacitance. As seen in FIG. 2, the illustrative release structure 20 includes a step at about the position of the spacer 18, due to the height difference between the first and second electrodes 10 and 12.

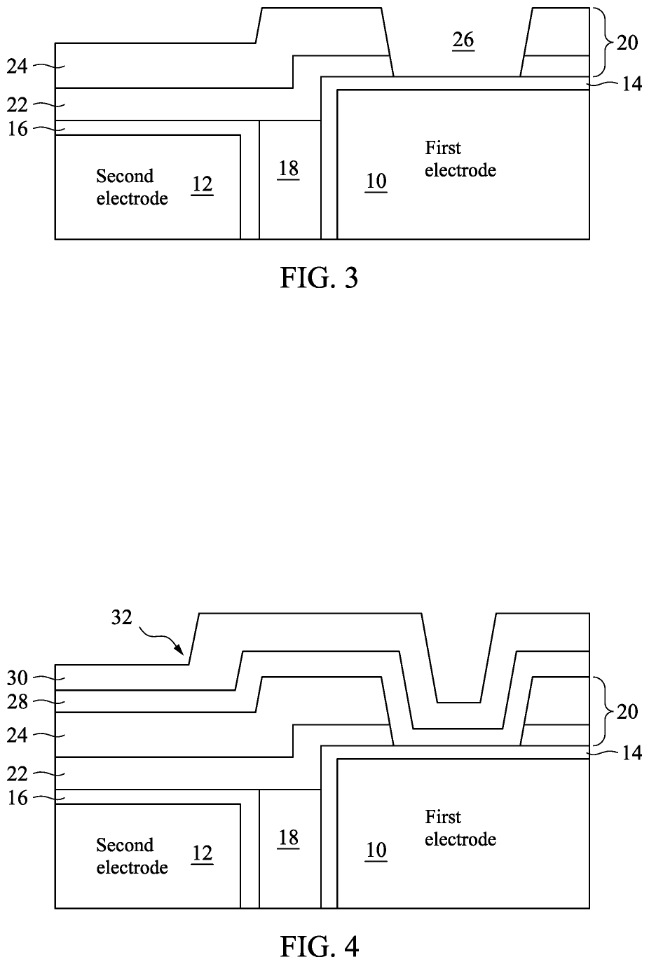

With reference now to FIG. 3, the cantilevered arm to be formed has one end anchored to an anchor. In the illustrative example, the anchor is the first electrode 10. Hence, as shown in FIG. 3, an opening 26 is formed in at least a portion of the release structure disposed over the first electrode 10, for example by photolithographically patterned etching of the release structure 20. In one suitable approach, the opening 26 is etched using a fluorine-based etchant that etches the silicon material of the release structure 20 but does not etch the first electrode protective dielectric layer 14, so that the first electrode protective dielectric layer 14 serves as an etch stop in etching the opening 26. The size of the opening 26 should be large enough to provide sufficient anchoring of the cantilevered arm to ensure structural reliability under credibly expected forces that may be applied to the cantilevered arm during use of the MEMS structure. In a nonlimiting illustrative example, the opening 26 has a circular area with a diameter of about 2-3 microns, although larger or smaller opening sizes are contemplated, as well as openings with non-circular area.

With reference now to FIG. 4, a lower protective dielectric layer 28 is deposited on at least the release structure 20, and in the illustrative example also in the opening 26; followed by forming an arm structure 30 which is disposed over the first electrode 10 and the second electrode 12 and over the spacer 18 therebetween. The arm structure 30 (with the lower protective dielectric layer 28) is destined to form the cantilevered arm 40 after the release step (see FIG. 5), with the cantilevered arm 40 having one end anchored to an anchor (in the illustrative example of FIG. 5 the anchor is the first electrode 10). For the illustrative capacitive MEMS structure being fabricated in the illustrative example of FIGS. 1-5, the cantilevered arm 40 is to be capacitively coupled with the second electrode 12—hence, the arm structure 30 (with the underlying lower protective dielectric layer 28) is also disposed over the second electrode 12 as seen in FIG. 4. The purpose of the lower protective dielectric layer 28 is to protect the lower surface of the arm structure 30 during the subsequent fluorine-based etching, as will be described with reference to FIG. 5.

The lower protective dielectric layer 28 in some nonlimiting illustrative embodiments comprises a silicon oxide (e.g., stoichiometric silicon dioxide, SiO₂, or a non-stoichiometric silicon oxide), a silicon nitride (e.g., stoichiometric Si₃N₄ or non-stoichiometric silicon nitride), a silicon carbide, a silicon oxynitrocarbide, or a glass such as USG, FSG, BPSG, or various combinations thereof, although other materials are also contemplated. These materials are highly resistant to etching by fluorine, thus providing protection for the lower surface of the arm structure 30 during the etching. The thickness of the lower protective dielectric layer 28 is chosen to provide sufficient protection for the underside of the arm structure 30 during the subsequent fluorine etching, which in turn depends on factors such as the type of material comprising the lower protective dielectric layer 28 and the properties of the fluorine etching such as the etching tool used, reagent concentrations, and the etch time. In some nonlimiting illustrative examples, the lower protective dielectric layer 28 may have a thickness of between 0.2 micron and 1 micron, although thicknesses outside this range are also contemplated.

The arm structure 30 is suitably formed as a layer disposed on the release structure 20 (with the protective dielectric layer 28 interposed therebetween, as seen in FIG. 4). The deposited arm structure 30 also coats the inside of the opening 26 to provide the destined anchoring of the cantilevered arm 40 to the anchor 10 (see FIG. 5). In some nonlimiting illustrative embodiments, the arm structure 30 comprises a metal (e.g. copper), a metal alloy (e.g., AlCu), AlSiCu, a metal nitride (e.g., TiN or TaN), or a combination thereof, although other materials are also contemplated. The material and the thickness of the arm structure 30 are chosen to provide the resulting cantilevered arm with the chosen design-basis properties, such as strength, flexibility, and so forth. In some nonlimiting illustrative examples, the arm structure 30 may have a thickness of between 0.2 micron and 1 micron, although thicknesses outside this range are also contemplated. The arm structure 30 (along with the underlying protective dielectric layer 28) conforms with the upper surface of the underlying release structure 20—hence, in the nonlimiting illustrative example the arm structure 30 has a bend 32 indicated in FIG. 4.

With reference to FIG. 5, the release structure 20 is removed by etching with a fluorine-based etchant (diagrammatically indicated in FIG. 5 by fluorine atoms 42. This results in release of the unanchored end of the arm structure 30 to form a MEMS arm 40, which in this embodiment is a cantilevered arm 40 that is secured to the anchor structure 10 at one end, and has the opposite end free to move in response to an electrical input across the electrodes 10 and 12, or in response to another type of stimulus such as sound waves, acceleration, or so forth. As seen in FIG. 5, the cantilevered arm 40 comprises the arm structure 30 and the lower protective dielectric layer 28. The etching may employ various etching tools and etching processes, such as reactive ion etching (RIE), inductively coupled plasma etching (ICP), remote plasma etching, or so forth, as some nonlimiting illustrative examples. The fluorine-based etchant includes fluorine or a fluorine compound as the active etching species. For example, the fluorine-based etchant may comprise CF₄ gas and/or SF₆ gas, as two nonlimiting illustrative examples. Fluorine is a highly reactive atom, and hence the active fluorine or a fluorine compound of the fluorine-based etchant efficiently etches the release structure 20, which as previously mentioned is formed of a silicon material such as silicon, polysilicon, amorphous silicon, or a combination thereof. As also seen by comparing FIGS. 4 and 5, the spacer 18 is removed by the fluorine-based etchant. To this end, the spacer 18 is made of a material that is etched by the fluorine-based etchant, such as a silicon material (e.g., silicon, polysilicon, amorphous silicon, or a combination thereof, although other materials besides silicon are also contemplated). The removal of the spacer 18 results in the first and second electrodes 10 and 12 being spaced apart from each other by the width of the (now-removed) spacer 18.

It will be appreciated that the first and second electrodes 10 and 12, while suitably made of a silicon material in some embodiments, are protected from the etching by the fluorine-based etchant by the respective first and second electrode protective dielectric layers 14 and 16, which are made of a suitably resistant material such as a silicon oxide, a silicon nitride, a silicon carbide, a silicon oxynitrocarbide, a glass, or various combinations thereof.

As previously mentioned, the arm structure 30 comprises a metal or metal alloy, a metal nitride, or a combination thereof. Fluorine-based etchants are typically highly selective for etching silicon material over metals, metal alloys, and/or metal nitrides. Said another way, fluorine-based etchants typically etch silicon material very rapidly; whereas, fluorine-based etchants either do not etch metals, metal alloys, and/or metal nitrides, or etch them at a much slower rate as compared with the etching rate of silicon material. Hence, the fluorine-based etchant used in the release step selectively etches and removes the release structure 20 of silicon material while leaving the arm structure 30, thereby releasing the arm structure 30 (except where it is anchored to the first electrode 10) to form the cantilevered arm 40. Hence, due to the high selectivity of the fluorine-based etching, it is not apparent that the lower protective dielectric layer 28 provides benefit.

However, it is recognized herein that fluorine-based etchants can attack the metal, metal alloy, or metal nitride material of the arm structure 30, albeit with a much slower etch rate compared with the etch rate of the silicon material of the release structure 20 (and the silicon material of the spacer 18). For example, in reference MEMS arm structures examined here, it was revealed by scanning electron microscopy (SEM) of the AlCu surfaces after etching with a fluorine-based etch that the surfaces included protrusions or other nonplanar features. Without being limited to any particular theory of operation, it is believed that these protrusions are produced by fluorine attacking the AlCu surface during the etching.

Based on this recognition that the fluorine-based etch can produce protrusions or other nonplanar features on the AlCu surface, it is disclosed herein to include the lower protective dielectric layer 28 to protect the lower surface of the arm structure 30 during the fluorine-based etching. As previously mentioned, the lower protective dielectric layer 28 in some nonlimiting illustrative embodiments comprises a silicon oxide, a silicon nitride, a silicon carbide, a silicon oxynitrocarbide, a glass, or various combinations thereof. These materials are impervious to, or at least highly resistant to, etching by a fluorine-based etchant. Hence, the lower protective dielectric layer 28 disposed on the lower surface of the arm structure 30 protects that lower surface from attack by the fluorine-based etchant. Without the lower protective dielectric layer 28, the fluorine etch would directly interact with the lower surface of the arm structure 30 potentially leading to formation of protrusions or other nonplanar features on the arm structure.

Protecting the arm structure 30, and particularly its lower surface, from fluorine attack by way of the lower protective dielectric layer 28 is beneficial because an attack by the fluorine-based etchant on the lower surface of the arm structure 30 can change the separation between the lower surface of the cantilevered arm and the upper surface of the second electrode 12. This separation, denoted as separation d in FIG. 5, is small, being approximately equal to the thickness of the release structure 20 (shown in FIG. 4, prior to its removal by the fluorine-based etching). The separation d may differ somewhat from the thickness of the release structure 20 due to factors such as sagging under gravitational force, and/or electrostatic attraction or repulsion due to electrostatic charge buildup on the second electrode 12 and/or on the cantilevered arm 40 which can attract or repel the cantilevered arm 40 toward or away from the second electrode 12, depending on the electrostatic charge polarity. As previously mentioned, in some nonlimiting illustrative embodiments the thickness of the release structure 20 is about 1-2 microns, although larger or smaller thicknesses are also contemplated-hence, in such embodiments the separation d is also about 1-2 microns, although larger or smaller separation values are also contemplated.

The separation d has a strong effect on the operation of the capacitive MEMS device. A voltage difference ΔV between the first and second electrodes 10 and 12 presents as a voltage difference ΔV between the cantilevered arm 40 and the second electrode 12 (neglecting any voltage drop along the cantilevered arm 40). The magnitude |Ē| of the electric field Ē present in the gap of separation d between the cantilevered arm 40 and the second electrode 12 is thus given by

$$\vert \overline{E} \vert = \frac{Δ V}{d} .$$

The small value of the separation d, along with this inverse relationship between |Ē| and d, means that a small change in the separation d due to fluorine attack on the lower surface of the cantilevered arm can significantly change the strength of the electric field |Ē| extant between the cantilevered arm 40 and the second electrode 12. Moreover, a fluorine attack on the lower surface of the cantilevered arm was observed in SEM to be spatially nonuniform, leading to surface roughness and/or protrusions. Without being limited to any particular theory of operation, it is believed this constitutes AlCu surface damage due to attack by the fluorine-based etchant. Such roughness and/or protrusions can locally modify the electrostatic potential difference between the cantilevered arm 40 and the second electrode 12, leading to localized areas of higher electric field at the protrusions, which in turn can lead to performance degradation and/or failure mechanisms such as coronal discharge at such a protrusion. By including the lower protective dielectric layer 28 as disclosed herein, such that the cantilevered arm 40 includes the arm structure 30 and the lower protective dielectric layer 28, these matters are alleviated.

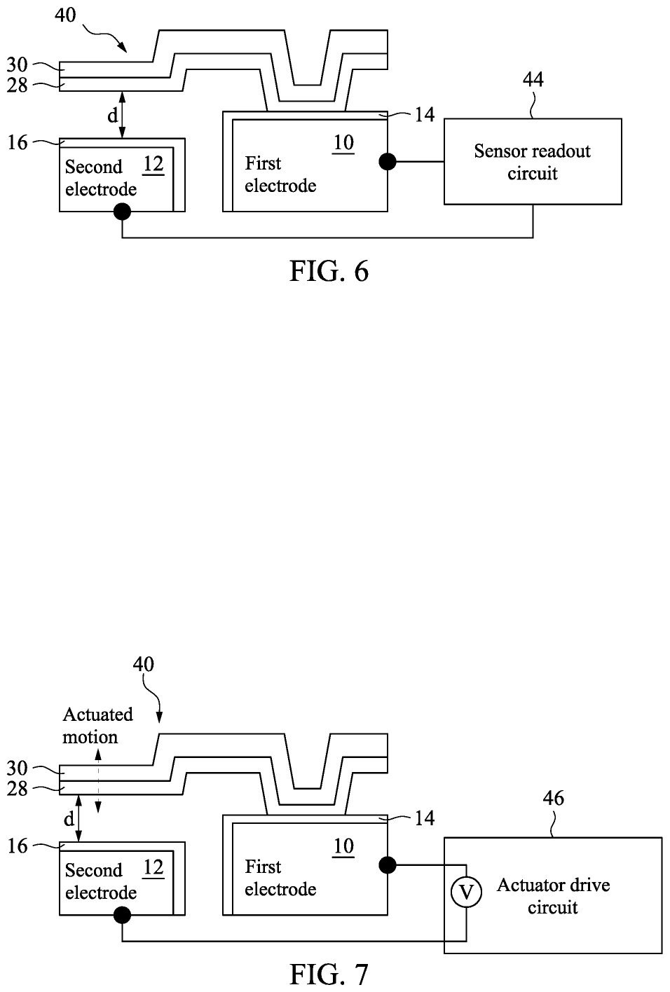

With reference to FIGS. 6 and 7, the illustrative capacitive MEMS device of FIG. 5 can be used in a sensor application (FIG. 6) or as an actuator (FIG. 7). In the sensor device of FIG. 6, a sensor readout circuit 44 measures the capacitance (or a related electrical parameter, such as voltage or current) across the first and second electrodes 10 and 12. If the cantilevered arm 40 moves in response to a stimulus, this will be detected as a change in the capacitance (or related electrical parameter) measured by the sensor readout circuit 44. The stimulus causing movement of the cantilevered arm 40 could, for example, be an acceleration (in which case the sensor device of FIG. 6 is suitably an accelerometer), or a sound wave, or so forth. In the actuator device of FIG. 7, an actuator drive circuit 46 applies a voltage difference (or other driving electrical signal such as an electric current) on the first and second electrodes 10 and 12, thereby causing electrostatic force (e.g., repulsion and/or attraction) between the second electrode 12 and the cantilevered arm 40 leading to actuated movement of the cantilevered arm away from the second electrode 12 (repulsive force) and/or toward the second electrode 12 (attractive force). If an alternating voltage or current (i.e., a.c. signal) is applied by the actuator drive circuit 46, then an oscillating movement of the cantilevered arm 40 can be produced. The resulting actuated motion can drive motion of an element connected to the cantilevered arm 40, or can produce a sound wave, or perform another useful motive function. In these nonlimiting illustrative applications, the sensor readout circuit 44 or actuator drive circuit 46 are suitably implemented as an electronic circuit comprising transistors, MOSFETs, and/or so forth.

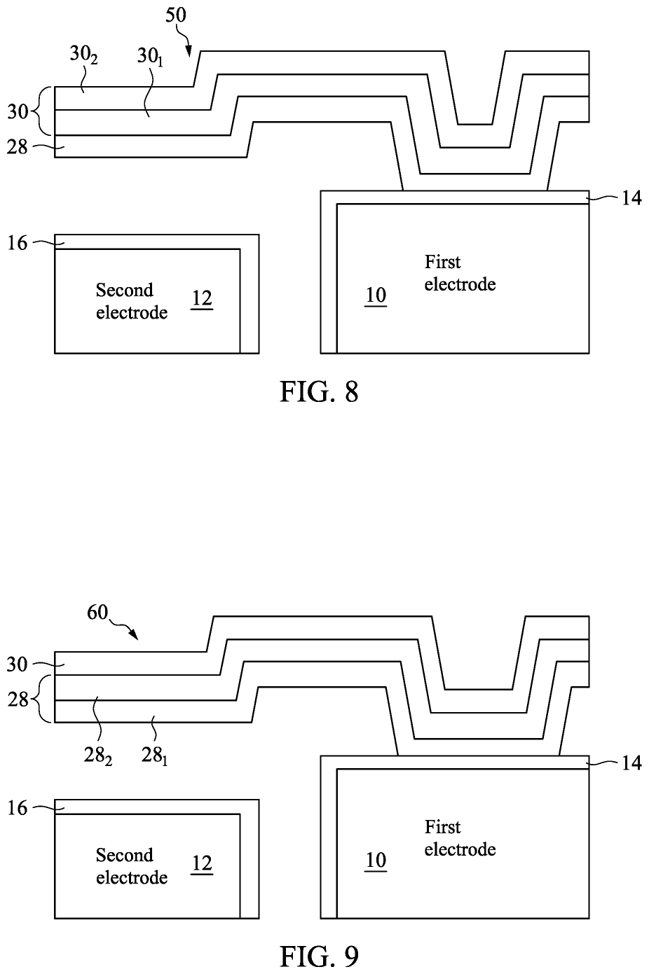

With reference to FIG. 8, a sectional view of another illustrative MEMS arm embodiment is shown. The MEMS arm of FIG. 8 is similar to the MEMS arm of FIG. 5, and includes the first and second electrodes 10 and 12, the first and second electrode protective dielectric layers 14 and 16, and the cantilevered arm 40 comprising the arm structure 30 and the lower protective dielectric layer 28. In the embodiment of FIG. 8, the arm structure 30 includes a stack of at least two layers of different materials 30₁ and 30₂, each layer comprising a metal, a metal alloy, a metal nitride, or a combination thereof. In the embodiment of FIG. 8, the cantilevered arm 50 includes the arm structure 30 comprising the stack of layers 30₁ and 30₂, and the lower protective dielectric layer 28. Fabrication of the MEMS arm of FIG. 8 follows the sequence described previously with reference to FIGS. 1-5, except that at the stage depicted in FIG. 4 the two layers 30₁ and 30₂ are deposited in succession.

In one contemplated application of the embodiment of FIG. 8, the two layers 30₁ and 30₂ can form a bimetallic thermometer. In such an embodiment, the two layers 30₁ and 30₂ are made of different metals with different coefficients of thermal expansion. Consequently, when the temperature of the arm structure 30 changes one metal expands (or contracts) faster than the other, causing the cantilevered arm 40 to bend toward or away from the second electrode 12, thus changing the capacitance. The change of capacitance (or of another correlated electrical parameter) can be measured by the sensor readout circuit 44 of FIG. 6 so as to provide a temperature sensor.

With reference to FIG. 9, a sectional view of another illustrative MEMS arm embodiment is shown. The MEMS arm of FIG. 9 is similar to the MEMS arm of FIG. 5, and includes the first and second electrodes 10 and 12, the first and second electrode protective dielectric layers 14 and 16, and the cantilevered arm 40 comprising the arm structure 30 and the lower protective dielectric layer 28. However, in the embodiment of FIG. 9, the lower protective dielectric layer 28 includes a dielectric layer stack including a first lower protective dielectric layer 28₁ and a second lower protective dielectric layer 28₂. Fabrication of the MEMS arm of FIG. 9 follows the sequence described previously with reference to FIGS. 1-5, except that at the stage depicted in FIG. 4 the deposition sequence includes deposition of the first lower protective dielectric layer 28₁ followed by deposition of the second lower protective dielectric layer 28₂ followed by deposition or other formation of the arm structure 30. The first lower protective dielectric layer 28₁ and the second lower protective dielectric layer 28₂ are suitably different fluorine etchant-resistant materials. For example, the first lower protective dielectric layer 28₁ may comprise a silicon oxide (e.g., stoichiometric silicon dioxide, SiO₂, or a non-stoichiometric silicon oxide), a silicon nitride (e.g., stoichiometric Si₃N₄ or non-stoichiometric silicon nitride), a silicon carbide, a silicon oxynitrocarbide, or a glass such as USG, FSG, BPSG, or various combinations thereof; and the second lower protective dielectric layer 28₂ may comprise a silicon oxide (e.g., stoichiometric silicon dioxide, SiO₂, or a non-stoichiometric silicon oxide), a silicon nitride (e.g., stoichiometric Si₃N₄ or non-stoichiometric silicon nitride), a silicon carbide, a silicon oxynitrocarbide, or a glass such as USG, FSG, BPSG, or various combinations thereof; wherein the first and second lower protective dielectric layers 28₁ and 28₂ are different materials. These again are merely some nonlimiting illustrative examples. In the embodiment of FIG. 9, a cantilevered arm 60 thus includes the arm structure 30 and the lower protective dielectric layer 28 with the latter being the dielectric layer stack including the first and second lower protective dielectric layers 28₁ and 28₂. While FIG. 9 illustrates a variant embodiment in which the lower protective dielectric layer 28 is a stack of two constituent dielectric layers 28₁ and 28₂, it will be appreciated this can be extended to three, four, or more constituent dielectric layers.

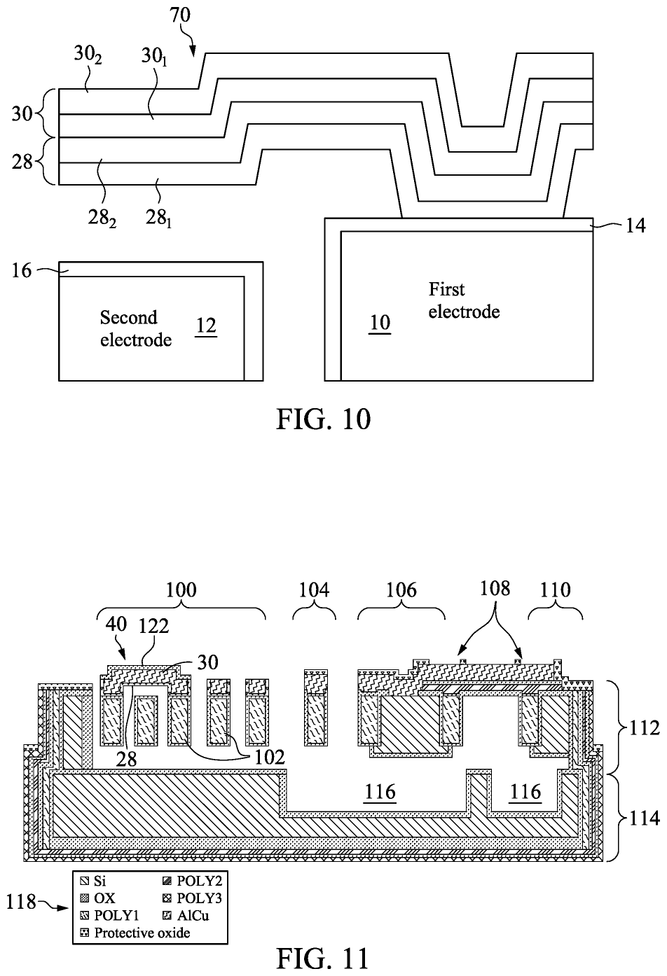

With reference to FIG. 10, a sectional view of another illustrative MEMS arm embodiment is shown. The MEMS arm of FIG. 10 effectively combines the embodiments of FIGS. 8 and 9 by forming the lower protective dielectric layer 28 as the dielectric layer stack including the first and second lower protective dielectric layers 28₁ and 28₂, as shown in FIG. 9, and also forming the arm structure 30 as a stack of two layers 30₁ and 30₂ made of different materials, to form the cantilevered arm 70 including the first and second lower protective dielectric layers 28₁ and 28₂, as described with reference to FIG. 9, and the two layers of different materials 30₁ and 30₂, as described with reference to FIG. 8.

The illustrative examples of FIGS. 1-10 are MEMS arms in which the MEMS arm is a cantilevered arm 40 (or 50, or 60, or 70) that is anchored at one end to a first electrode 10 and has its unanchored (i.e., free) end positioned near to a second electrode 12 (e.g., with the separation d as indicated in FIGS. 5-7). This forms a capacitive MEMS device, in which capacitance between the cantilevered arm and the second electrode 12 can be leveraged to perform sensing functionality (e.g., FIG. 6) or can be operated as a capacitive actuator (e.g., FIG. 7). Although not shown, the free end of the cantilevered arm 40 could be connected with a component such as a comb, so that movement of the cantilevered arm 40 causes movement of the comb (or other component) that is attached to the free end of the cantilevered arm 40. It will be appreciated that other types of MEMS arms could be similarly fabricated. As another example, instead of a cantilevered arrangement, the MEMS arm could instead be secured to (i.e., suspended between) anchors at both ends of the arm, and the middle portion of the MEMS arm could flex (while both ends remain anchored) in response to an electrical input, sound wave, or other type of stimulus. In another example, the MEMS arm could be a spring secured at both ends. These are merely further nonlimiting examples. In any such embodiments, the MEMS arm comprises a cantilevered or suspended arm of metal, a metal alloy, a metal nitride, or a combination thereof that is released by removing a release layer using etching with a fluorine-based etchant. For example, the approaches disclosed herein can be useful when fabricating a MEMS spring structure comprising a suspended arm of metal, a metal alloy, a metal nitride, or a combination thereof.

With reference to FIG. 11, a cut line view is shown of a MEMS device including a driving comb 100 comprising a comb 102 secured with a cantilevered arm comprising the cantilevered arm 40 including the arm structure 30 and the lower protective oxide 28. The comb 102 may, for example, comprise polysilicon (as shown in FIG. 11), or silicon, amorphous silicon, or a combination thereof, and may be coated with a protective dielectric layer such as an oxide that is not removed by the etching with the fluorine-based etchant, as further shown in FIG. 11. Comb drives can be used, for example, in MEMS-based accelerometers, where the acceleration is detected as a change in the capacitance of the comb drive structure. When used as a sensor, an external condition such as sound waves (or, more generally, pressure waves), light, magnetic signals or the like are converted by the comb drive to an electrical signal such as voltage or current. Conversely, when used as an actuator, an applied electrical signal such as voltage or current drives movement of a comb which can serve as a transducer for generating sound or other types of signals. Hence, the sensing or actuating operation is similar to that described with reference to respective FIG. 6 or FIG. 7, but the comb 102 secured with the cantilevered arm 40 to provide greater area for electrostatic interaction. The illustrative MEMS device of FIG. 11 further includes a spring 104, a middle frame 106, metal spring 108, and an outer frame 110. These components are all fabricated in a first (e.g., upper) wafer 112, which is bonded to a second (e.g., lower) wafer 114 having cavities 116 formed therein. A legend 118 indicates the materials used in the MEMS device of FIG. 11.

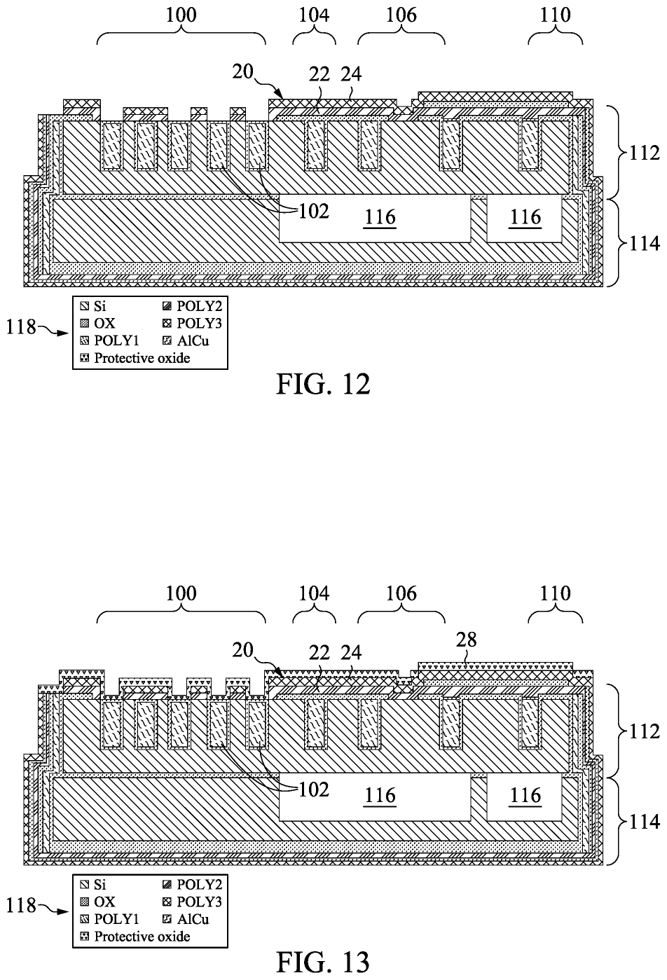

With reference to FIGS. 12-18, cut line views are shown of intermediate structures of a fabrication process for fabricating the illustrative MEMS device of FIG. 11. Note that the same reference numbers are used in the successive fabrication step cut views of FIGS. 12-18, and only reference numbers relevant to the step shown in a given cut view are discussed with reference to that cut view. FIGS. 12-18 each also include the legend 118 and use the same hatchings to indicate various materials as labeled in the legend 118.

FIG. 12 illustrates the cut line view for the device fabrication at the stage where the comb 102 has been formed in the silicon of the upper wafer 112, and the lower wafer 114 has been processed to form the cavities 116 and bonded with the upper wafer 112. Also seen in FIG. 12 is the release layer 20 formed of the two different layers 22 and 24 of different silicon materials, as previously discussed with reference to FIG. 2.

FIG. 13 shows the cut line view after deposition of the lower protective dielectric layer 28. As seen in FIG. 13, the lower protective dielectric layer 28 is deposited as a conformal blanket layer which coats the entire upper surface.

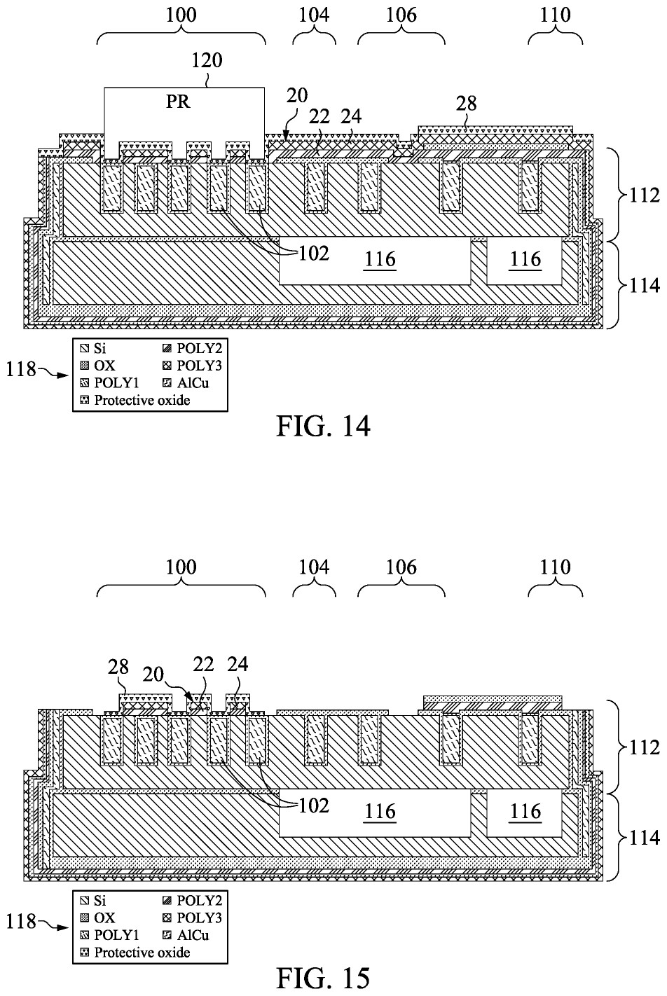

FIG. 14 shows the cut line view after application of photoresist 120 for performing etching of the lower protective dielectric layer 28. The photoresist is deposited as a blanket layer of photoresist, followed by patterning which as seen in FIG. 14 leaves the patterned photoresist 120 covering only the area corresponding to the driving comb 100.

FIG. 15 shows the cut line view after the etching of the lower protective dielectric layer 28 and stripping of the photoresist 120. The etching removes the blanket lower protective dielectric layer 28 except where it is protected by the patterned photoresist 120 shown in FIG. 14; hence, after the etching the remaining lower protective dielectric layer 28 coats only the area of the driving comb 100, as seen in FIG. 15.

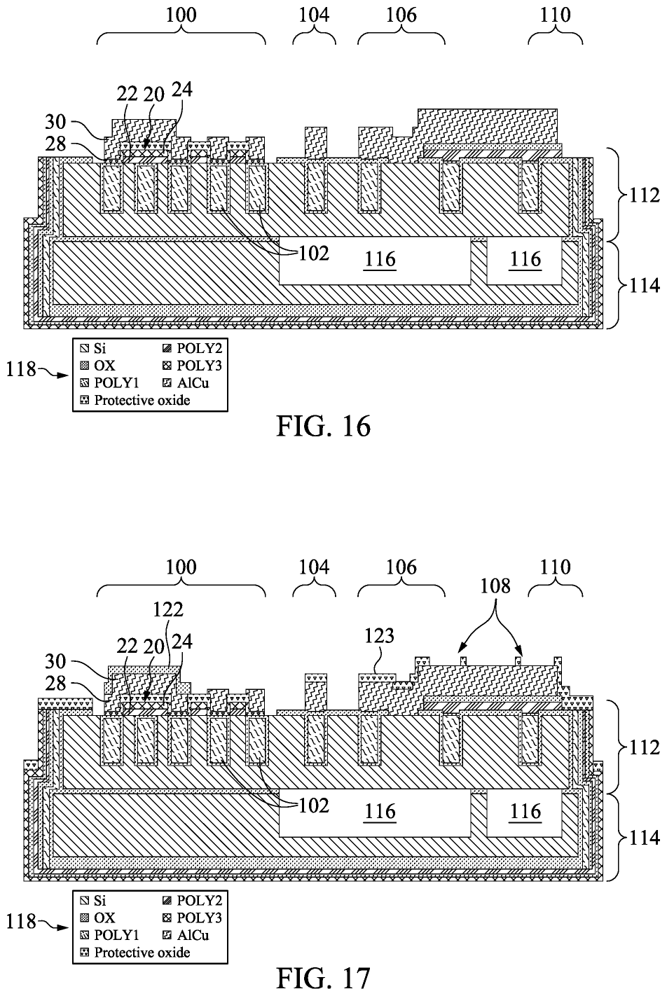

FIG. 16 shows the cut line view after deposition and photolithographically patterned etching of the AlCu arm structure 30. As seen in FIG. 16, the deposited and patterned AlCu layer is disposed in the area of the driving comb 100, and is also disposed in the areas of the spring 104 and middle frame 106. Hence, the spring 104 is made of the same material (illustrative AlCu) as the arm structure 30.

FIG. 17 shows the cut line view after deposition of a passivation oxide layer 122 over the arm structure 30. FIG. 17 also shows a deposited and patterned protective oxide 123 disposed over the spring 104, the middle frame 106, the outer frame 110, and portions of the area destined to become the metal spring 108. Areas of the metal spring 108 which are not coated with the protective oxide 123 suitably serve as a metal pad.

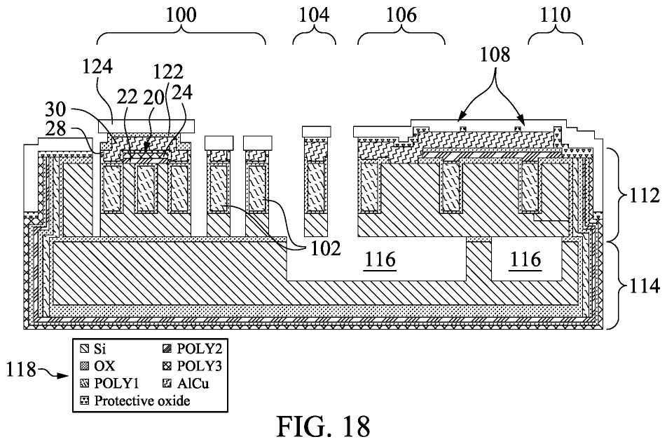

FIG. 18 shows the cut line view after a photolithographically controlled silicon etching step. FIG. 18 illustrates some remaining photoresist 124 (e.g., at least 4 microns thickness in some embodiments).

With return to FIG. 11, the cut line view after release of the arm 30 using a fluorine-based etchant is shown. The photolithographically controlled etching of FIG. 18 forms openings for ingress of the fluorine-based etchant used to release the arm 30 by removing the silicon release layer 20 (which in the illustrative example includes two layers 22 and 24 of different silicon materials). Since the fluorine-based etchant removes silicon, surfaces of silicon regions which are to remain after the fluorine-based etching are suitably protected during the etching by a protective oxide coating, e.g., the cavities 116 and other exposed surface of the lower wafer 114 are coated with protective oxide as shown in FIG. 11.

In the following, some further embodiments are described.

In a nonlimiting illustrative embodiment, a method of fabricating a microelectromechanical (MEMS) structure is disclosed. The method comprises: forming a release structure disposed on a base structure wherein the base structure includes an anchor structure; depositing a lower protective dielectric layer on at least the release structure; forming an arm structure disposed on the lower protective dielectric layer and on the anchor structure; and removing the release structure by etching with a fluorine-based etchant to form a MEMS arm that is secured to the anchor structure, the MEMS arm comprising the arm structure and the lower protective dielectric layer.

In a nonlimiting illustrative embodiment, a method of fabricating a MEMS structure is disclosed. The method comprises: providing a capacitive drive including a first electrode and a second electrode; forming a release structure comprising a silicon material disposed on the second electrode; depositing a lower protective dielectric layer on at least the release structure; forming an arm structure disposed on the lower protective dielectric layer and on the first electrode; and removing the release structure by etching with a fluorine-based etchant to form a cantilevered arm that is secured to the first electrode and that is capacitively coupled with the second electrode, the cantilevered arm comprising the arm structure and the lower protective dielectric layer.

In a nonlimiting illustrative embodiment, a MEMS structure includes: a first electrode; a second electrode; and a cantilevered arm that is secured to the first electrode and that is above the second electrode with a gap in between. The cantilevered arm includes an arm structure and a lower protective dielectric layer disposed on an underside of the arm structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a microelectromechanical (MEMS) structure, the method comprising:
forming a release structure disposed on a base structure wherein the base structure includes an anchor structure;
depositing a lower protective dielectric layer on at least the release structure;
forming an arm structure disposed on the lower protective dielectric layer and on the anchor structure; and
removing the release structure by etching with a fluorine-based etchant to form a MEMS arm that is secured to the anchor structure, the MEMS arm comprising the arm structure and the lower protective dielectric layer.

2. The method of claim 1, wherein:
the release structure comprises silicon, polysilicon, amorphous silicon, or a combination thereof; and
the arm structure comprises a metal, a metal alloy, a metal nitride, or a combination thereof.

3. The method of claim 2, wherein the lower protective dielectric layer comprises a silicon oxide, a silicon nitride, a silicon carbide, a silicon oxynitrocarbide, a glass, or a combination thereof.

4. The method of claim 1, wherein the lower protective dielectric layer is deposited at least on the release structure and the anchor structure.

5. The method of claim 1, wherein the arm structure includes a stack of at least two layers of different materials, each layer comprising a metal, a metal alloy, a metal nitride, or a combination thereof.

6. The method of claim 1, wherein the lower protective dielectric layer comprises a dielectric stack including at least two different dielectric layers.

7. The method of claim 1, wherein:
the anchor structure of the base structure comprises a first electrode,
the base structure further comprises a second electrode and a spacer interposed between the first electrode and the second electrode, the release structure being disposed on the second electrode and on the spacer;
the etching with the fluorine-based etchant further removes the spacer; and
the MEMS structure fabricated by the method comprises a capacitive MEMS structure in which the MEMS arm is capacitively coupled with the second electrode.

8. The method of claim 7, wherein:
the first electrode comprises silicon, polysilicon, amorphous silicon, or a combination thereof coated with a first electrode protective dielectric layer that is not removed by the etching with the fluorine-based etchant;
the second electrode comprises silicon, polysilicon, amorphous silicon, or a combination thereof coated with a second electrode protective dielectric layer that is not removed by the etching with the fluorine-based etchant; and
the spacer comprises silicon, polysilicon, amorphous silicon, or a combination thereof.

9. The method of claim 7, further comprising:
forming a comb secured with the arm structure, the comb comprising silicon, polysilicon, amorphous silicon, or a combination thereof coated with a comb structure protective dielectric layer that is not removed by the etching with the fluorine-based etchant;
wherein the capacitive MEMS structure comprises a comb drive.

10. A method of fabricating a microelectromechanical (MEMS) structure, the method comprising:
providing a capacitive drive including a first electrode and a second electrode;
forming a release structure comprising a silicon material disposed on the second electrode;
depositing a lower protective dielectric layer on at least the release structure;
forming an arm structure disposed on the lower protective dielectric layer and on the first electrode; and
removing the release structure by etching with a fluorine-based etchant to form a cantilevered arm that is secured to the first electrode and that is capacitively coupled with the second electrode, the cantilevered arm comprising the arm structure and the lower protective dielectric layer.

11. The method of claim 10, wherein the silicon material of the release structure comprises silicon, polysilicon, amorphous silicon, or a combination thereof.

12. The method of claim 10, wherein the fluorine-based etchant comprises CF₄, SF₆, or a combination thereof.

13. The method of claim 10, wherein the lower protective dielectric layer is deposited at least on the release structure and the first electrode.

14. The method of claim 10, wherein the arm structure is formed with two layers of different materials.

15. The method of claim 10, wherein the lower protective dielectric layer comprises a dielectric stack including at least two different dielectric layers.

16. A microelectromechanical (MEMS) structure comprising:
a first electrode;
a second electrode; and
a cantilevered arm that is secured to the first electrode and that is above the second electrode with a gap in between, the cantilevered arm including an arm structure and a lower protective dielectric layer disposed on an underside of the arm structure.

17. The MEMS structure of claim 16, further comprising:
a comb secured with the cantilevered arm, wherein the capacitive MEMS structure comprises a comb drive.

18. The MEMS structure of claim 17, further comprising:
at least one spring comprising the same material as the arm structure.

19. The MEMS structure of claim 16, wherein the arm structure comprises a metal, a metal alloy, a metal nitride, or a combination thereof.

20. The MEMS structure of claim 16, wherein the arm structure includes a bend.
